(19) United States
(12) Patent Application Publication
(10) Pub. No.: US 2013/0313518 A1
(43) Pub. Date: Nov. 28, 2013

(54) SEMICONDUCTOR LIGHT EMITTING DEVICE

(71) Applicant: SAMSUNG ELECTRONICS CO., LTD., Suwon-si (KR)

(72) Inventors: Jong Uk SEO, Suwon (KR); Eun Deok SIM, Yongin (KR); Sang Don LEE, Suwon (KR); Hyun Kwon HONG, Cheonan (KR)

(21) Appl. No.: 13/902,610

(22) Filed: May 24, 2013

(30) Foreign Application Priority Data
May 25, 2012 (KR) 10-2012-0055966

(51) Int. Cl. H01L 33/24

(52) U.S. Cl. CPC H01L 33/24
USPC 257/13

(57) ABSTRACT

A semiconductor light emitting device includes first and second conductivity-type semiconductor layers formed of AlₓGa_{y}In_{1-x-y}P (0≦x≦1, 0≦y≦1, 0≦x+y≦1) or Al_{z}Ga_{1-z}As (0≦z≦1) and an active layer interposed between the first and second conductivity-type semiconductor layers, wherein at least one of the first and second conductivity-type semiconductor layers includes a low refractive index surface layer formed of (AlᵥGa₁₋ᵥ)_{0.5}In_{0.5}P (0.7≦v≦1) or Al_{w}In_{1-w}P (0≦w≦1) and having depressions and protrusions.

### CROSS-REFERENCE TO RELATED APPLICATION

This application claims priority of Korean Patent Application No. 10-2012-0055966 filed on May 25, 2012, in the Korean Intellectual Property Office, the disclosure of which is incorporated herein by reference in its entirety.

### BACKGROUND OF THE DISCLOSURE

1. Field of the Disclosure

The present disclosure relates to a semiconductor light emitting device.

2. Description of the Related Art

A light emitting diode (LED) is a semiconductor device capable of generating light of various colors according to electron hole recombination at p-type and n-type semiconductor junctions when an electrical current is applied thereto. Compared with a filament-based light emitting device, a semiconductor light emitting device has various advantages such as a long lifetime, low power consumption, excellent initial driving characteristics, high resistance to vibrations, and the like Accordingly, demand for semiconductor light emitting devices has continued to grow.

Luminance efficiency of a semiconductor light emitting device is determined by internal quantum efficiency and light extraction efficiency. Light extraction efficiency can be determined by optical factors of a light emitting device, e.g., a refractive index and/or interface flatness, and the like, of each structure. A structure (e.g., semiconductor material) of a light emitting device may have a refractive index of 2.5 or more, and may have a refractive index of 3.0 or more in the case of a red color (or a redish color group). Thus, light extraction efficiency is so low that high optical power can not be obtained, even when internal quantum efficiency is relatively high.

### SUMMARY OF THE DISCLOSURE

An object of the present disclosure is to provide a semiconductor light emitting device having improved optical power.

According to an aspect of the present disclosure, there is provided a semiconductor light emitting device including: first and second conductivity-type semiconductor layers formed of AlₓGa_{y}In_{1-x-y}P (1≦x≦1, 0≦y≦1, 0≦x+y≦1) or Al_{z}Ga_{1-z}As (0≦z≦1); and an active layer interposed between the first and second conductivity-type semiconductor layers, wherein at least one of the first and second conductivity-type semiconductor layers may include a low refractive index surface layer formed of (AlᵥGa₁₋ᵥ)_{0.5}In_{0.5}P (0.7≦v≦1) or Al_{w}In_{1-w}P (0≦w≦1) and having depressions and protrusions.

The low refractive index surface layer may be formed of Al_{w}In_{1-w}P (0.3≦w≦1).

The semiconductor light emitting device may further include an intermediate layer interposed between the low refractive index surface layer and the active layer, the intermediate layer may have a refractive index greater than that of the low refractive index surface layer.

The intermediate layer may be formed of AlᵤIn₁₋ᵤP (0≦u≦v, w).

The intermediate layer may be formed of AlₘGaₙIn₁₋ₘ₋ₙP (0≦m≦1, 0≦n≦1).

The semiconductor light emitting device may further include a plurality of intermediate layers interposed between the low refractive index surface layer and the active layer, wherein the plurality of intermediate layers may have refractive indices gradually decreased in a direction toward the low refractive index surface layer.

The plurality of intermediate layers may be formed of AlᵤIn₁₋ᵤP (0≦u≦1) and the proportions of aluminum (Al) of the plurality of intermediate layers may be gradually increased in a direction toward the low refractive index surface layer.

The plurality of intermediate layers may be formed of AlₘGaₙIn₁₋ₘ₋ₙP (0.3≦m≦1, 0≦n≦1) and the proportions of aluminum (Al) of the plurality of intermediate layers may be gradually increased in a direction toward the low refractive index surface layer.

The semiconductor light emitting device may further include an anti-reflective layer formed on the low refractive index surface layer.

The anti-reflective layer may be formed of a silicon nitride or a silicon oxide.

The semiconductor light emitting device may further include a first electrode electrically connected to the first conductivity-type semiconductor layer and a second electrode electrically connected to the second conductivity-type semiconductor layer.

The semiconductor light emitting device may further include a first contact layer interposed between the first conductivity-type semiconductor layer and the first electrode, and a second contact layer interposed between the second conductivity-type semiconductor layer and the second electrode.

According to another aspect of the present disclosure, there is provided a semiconductor light emitting device including: a first conductivity-type semiconductor layer; a second conductivity-type semiconductor layer; and an active layer interposed between the first and second conductivity-type semiconductor layers, wherein at least one of the first and second conductivity-type semiconductor layers includes an irregular surface.

The irregular surface may face away from the active layer.

The irregular surface may form an interface with air.

The at least one of the first and second conductivity-type semiconductor layers may include a low refractive index surface layer formed of (AlᵥGa₁₋ᵥ)_{0.5}In_{0.5}P (0.7≦v≦1) or Al_{w}In_{1-w}P (0≦w≦1), the irregular surface being formed on the low refractive index surface layer.

The at least one of the first and second conductivity-type semiconductor layers may have a refractive index which increases in a direction toward the active layer.

The at least one of the first and second conductivity-type semiconductor layers is formed of (AlᵥGa₁₋ᵥ)_{0.5}In_{0.5}P (0.7≦v≦1) or Al_{w}In_{1-w}P (0≦w≦1).

### BRIEF DESCRIPTION OF THE DRAWINGS

The above and other aspects, features and other advantages of the present disclosure will be more clearly understood from the following detailed description taken in conjunction with the accompanying drawings, in which:

FIG. 1 is a view schematically illustrating a cross-section of a light emitting device according to an exemplary embodiment of the present disclosure;

FIG. 2 is a graph showing a comparison of optical power of a light emitting device according to an exemplary embodiment of the present disclosure and that of a light emitting device according to a comparative example;

FIGS. 3A and 3B are conceptual views illustrating a light extraction principle according to the presence or absence of depressions and protrusions;

FIG. 4 is a view schematically illustrating a cross-section of a light emitting device according to another exemplary embodiment of the present disclosure;

FIG. 5 is a view schematically illustrating a cross-section of a light emitting device according to another exemplary embodiment of the present disclosure;

FIG. 6 is a graph showing a change in light extraction efficiency according to refractive indies of a low refractive index surface layer in a semiconductor light emitting device according to an exemplary embodiment of the present disclosure; and

FIG. 7 is a cross-sectional view schematically illustrating a package mounting form of the semiconductor light emitting device of FIG. 1.

### DETAILED DESCRIPTION OF PREFERRED EMBODIMENTS

Exemplary embodiments of the present disclosure will now be described in detail with reference to the accompanying drawings.

The present disclosure may, however, be embodied in many different forms and should not be construed as being limited to the exemplary embodiments set forth herein. Rather, these embodiments are provided so that this disclosure will be thorough and complete, and will fully convey examples within the scope of the disclosure to those having ordinary skill in the art. In the drawings, the shapes and dimensions of elements may be exaggerated for clarity, and the same reference numerals will be used throughout to designate the same or like components.

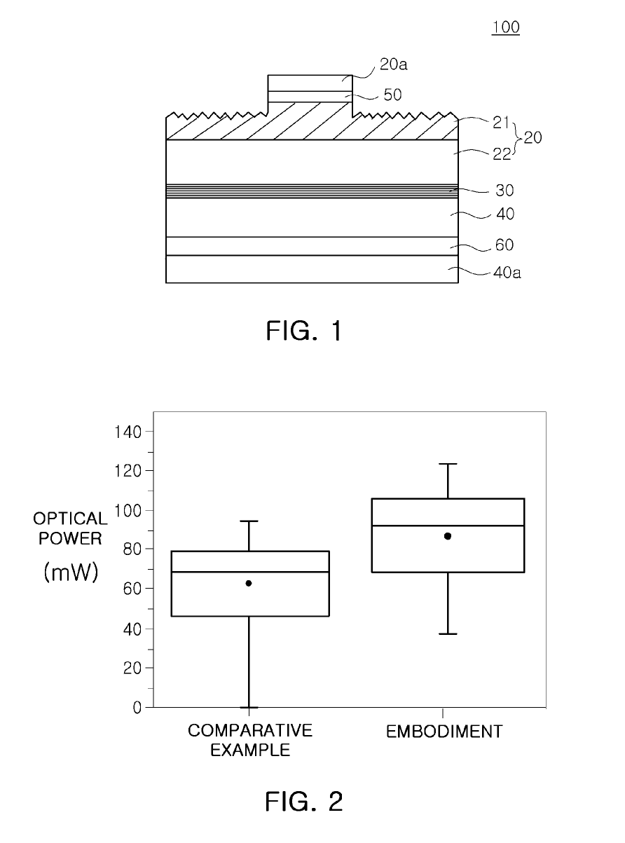

FIG. 1 is a view schematically illustrating a cross-section of a light emitting device according to an exemplary embodiment of the present disclosure.

Referring to FIG. 1, a light emitting device 100 includes first and second conductivity-type semiconductor layers 20 and 40 and an active layer 30 interposed between the first and second conductivity-type semiconductor layers 20 and 40. At least one of the first and second conductivity-type semiconductor layers 20 and 40 may include a low refractive index surface layer (or low refractive index coating) 21.

Each of the first and second conductivity-type semiconductor layers 20 and 40 may further include first and second electrodes 20a and 40a for receiving an electrical signal from an external source, respectively. A first contact layer 50 may be interposed between the first conductivity-type semiconductor layer 20 and the first electrode 20a, and a second contact layer 60 may be interposed between the second conductivity-type semiconductor layer 40 and the second electrode 40a.

In the present exemplary embodiment, the first and second conductivity-type semiconductor layers 20 and 40 may be an n-type semiconductor layer and a p-type semiconductor layer, respectively, and may be formed of an AlGaInP-based or AlGaAs-based semiconductor layer. Thus, in the present exemplary embodiment, the first and second conductivity-types may correspond to n-type and p-type conductivities, respectively, but the present disclosure is not limited thereto (e.g., the first and second conductivity-types may correspond to p-type and n-type conductivities, respectively).

In detail, the first and second conductivity-type semiconductor layers 20 and 40 may have an empirical formula AlₓGa_{y}In_{1-x-y}P (0≦x≦1, 0≦y≦1, 0≦x+y≦1) or Al_{z}Ga_{1-z}As (0≦z≦1). The active layer 30 formed between the first and second conductivity-type semiconductor layers 20 and 40 emits light having a certain level of energy according to electron and hole recombination, and may have a multi-quantum well (MQW) structure in which quantum well layers and quantum barrier layers are alternately laminated. Here, the MQW structure may be, for example, an AlGaInP/GaInP structure.

At least one of the first and second conductivity-type semiconductor layers 20 and 40 may have the low refractive index surface layer 21. The low refractive index surface layer 21 may be formed of (AlᵥGa₁₋ᵥ)_{0.5}In0.5P(0.7≦v≦1) or Al_{w}In_{1-w}P(0≦w≦1) and may have a structure in which at least a portion thereof has depressions and protrusions. The low refractive index surface layer 21 may be disposed in a light extraction path of at least one of the first and second conductivity-type semiconductor layers 20 and 40 to enhance light extraction efficiency of the light emitting device.

In the case of the AlGaInP or AlGaAs-based light emitting device, an active layer may emit light having a peak wavelength of 570 nm or higher, and a crystal can be grown on a GaAs substrate under lattice matching conditions, thereby obtaining internal quantum efficiency of about 90% or higher. However, a group III arsenide or phosphide-based semiconductor has a relatively high refractive index in comparison to other compound semiconductors. Thus, a critical angle at which total internal reflection occurs from an interface with air is so small that only an amount of light of about 2% or less of the entirety of light is extracted without total internal reflection. Thus, in the case of the light emitting device including a group III arsenide or phosphide-based semiconductor layer, light extraction efficiency acts as a critical factor in luminous efficiency.

In the present exemplary embodiment, the relatively low refractive index surface layer 21 having the composition of (AlᵥGa₁₋ᵥ)_{0.5}In_{0.5}P (0.7≦v≦1) or Al_{w}In_{1-w}P (0≦w≦1) is formed in an optical path of the light emitting device, thus effectively improving light extraction efficiency.

In general, band gap energy is lowered as a refractive index of a semiconductor layer is higher, and in the case of the group III arsenide or phosphide-based semiconductor layer, with a compound having a higher composition ratio of aluminum (Al), a band gap can be increased and a refractive index can be reduced. In particular, in case of forming depressions and protrusions on a surface of a semiconductor layer having the composition of, e.g., (AlᵥGa₁₋ᵥ)_{0.5}In_{0.5}P (0.7≦v≦1) or Al_{w}In_{1-w}P(0≦w≦1), light extraction efficiency is remarkably enhanced.

For example, in the case that light having a peak wavelength of 620 nm and Lambertian distribution is emitted from the active layer 30 to proceed into the air, if a quantity of light when an uppermost surface layer(e.g., the low refractive index surface layer 21 in the present exemplary embodiment) of the first conductivity-type semiconductor layer 20 has an empirical formula of Al_{0.3}Ga_{0.7}In_{0.5}P (refractive index: 3.355, critical angle: 17.34°) and a quantity of light when the low refractive index surface layer 21 of the first conductivity-type semiconductor layer 20 has an empirical formula of Al_{0.5}In_{0.5}P (refractive index: 2.953, critical angle:)19.79°) are compared, it can be seen that when the low refractive index surface layer 21 of the first conductivity-type semiconductor layer 20 has the empirical formula of Al_{0.5}In_{0.5}P, a quantity of light can be emitted without total internal reflection being increased by about 13.60% as expressed by equation 1 shown below.

$$\frac{{f}_{0}^{19.79} cos Θ d Θ - {f}_{0}^{17.34} cos Θ d Θ}{{f}_{0}^{17.34} cos Θ d Θ} = 13.60 \% \qquad [ Equation 1 ]$$

FIG. 2 is a graph showing a comparison of optical power of a light emitting device according to an exemplary embodiment of the present disclosure and that of a light emitting device according to a comparative example. In detail, the graph shows the results of a simulated experiment using an exemplary embodiment of the present disclosure in which the low refractive index surface layer 21 has the empirical formula of Al_{0.5}In_{0.5}P and a comparative example in which a first conductivity-type semiconductor layer disposed in the same position as that of the low refractive index surface layer has an empirical formula of (Al_{0.3}Ga_{0.7})_{0.5}In_{0.5}P.

In the experiment, after a silicon nitride layer (Si₃N₄) or a silicon oxide layer (SiO₂) were formed as an anti-reflective layer on the low refractive index surface layer of the exemplary embodiment and on the first conductivity-type semiconductor layer of the comparative example, measurement results were compared. The other remaining conditions, excluding the composition of the low refractive index surface layer, were the same.

The results illustrated in FIG. 2 show a comparison of optical power (mW) at a current of about 400 mA. It can be seen that when the low refractive index surface layer has the composition of Al_{0.5}In_{0.5}P, optical power was significantly increased from about 69.0 mW to 92.7 mW, in comparison to the case of the (Al_{0.3}Ga_{0.7})_{0.5}In_{0.5}P composition.

Meanwhile, the low refractive index surface layer may have a structure having depressions and protrusions formed thereon. If the low refractive index surface layer has a smooth structure without depressions and protrusions, the effect of enhancing light extraction efficiency by the low refractive index surface layer may be substantially hindered.

Table 1 below shows light extraction efficiency according to the presence and absence of depressions and protrusions in the light emitting devices according to the comparative example and the exemplary embodiment of the present disclosure.

TABLE 1

| | |
|---|---|
| Without depressions | With depressions and |
| and protrusions | protrusions |

| | Si₃N₄ | SiO₂ | Si₃N₄ | SiO₂ |
|---|---|---|---|---|
| Comparative | 8.10 | 7.81 | 11.50 | 11.11 |
| example | | | | |
| Embodiment | 8.06 | 8.10 | 12.89 | 12.93 |

Referring to Table 1, when depressions and protrusions were not formed on the low refractive index surface layer (i.e., ‘without depressions and protrusions’), namely, when the low refractive index surface layer had a smooth surface, there was little change in light extraction efficiency based on a difference in compositions; and when an anti-reflective layer was made of silicon nitride (Si₃N₄), light extraction efficiency was reduced from 8.10% to 8.06%.

Meanwhile, it can be seen that, when depressions and protrusions were formed on the low refractive index surface layer (i.e., ‘with depressions and protrusions’), light extraction efficiency was significantly increased in both cases in which the anti-reflective layer was made of silicon nitride (Si₃N₄) and (SiO₂).

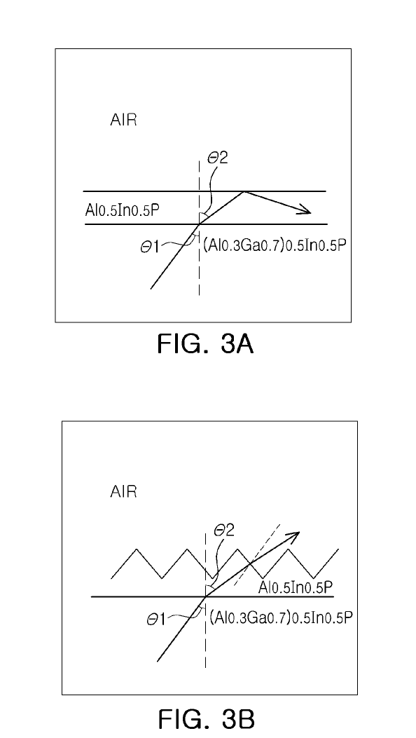

FIGS. 3A and 3B are conceptual views illustrating a light extraction principle according to the presence or absence of depressions and protrusions. Specifically, a comparison between a light extraction path when the low refractive index surface layer (Al_{0.5}In_{0.5}P) had a smooth surface (FIG. 3A) and that when it had depressions and protrusions (FIG. 3B) is shown.

First, referring to FIG. 3A, when the low refractive index surface layer (Al_{0.5}In_{0.5}P) does not have depressions and protrusions, light made incident to the low refractive index surface layer (Al_{0.5}In_{0.5}P) from an adjacent semiconductor layer ((Al_{0.3}Ga_{0.7})_{0.5}In_{0.5}P) having a relatively small refractive index, has a refraction angle θ₂ greater than an incident angle θ₁. Thus, although the critical angle at the interface of the low refractive index surface layer (Al_{0.5}In_{0.5}P) and air is increased due to the low refractive index of the low refractive index surface layer (Al_{0.5}In_{0.5}P), the effect of the increased critical angle is substantially canceled out due to light being refracted to have a great refraction angle θ₂ from the adjacent semiconductor layer ((Al_{0.3}Ga_{0.7})_{0.5}In_{0.5}P) to the low refractive index surface layer (Al_{0.5}In_{0.5}P).

Meanwhile, when depressions and protrusions are formed on the surface of the low refractive index surface layer (Al_{0.5}In_{0.5}P), although light made incident from the adjacent semiconductor layer ((Al_{0.3}Ga_{0.7})_{0.5}In_{0.5}P) to the low refractive index surface layer (Al_{0.5}In_{0.5}P) has the refraction angle θ₂ greater than the incident angle θ₁, the irregular surface of the low refractive index surface layer (Al_{0.5}In_{0.5}P) having an interface with air forms an angle with a surface having an interface with the adjacent semiconductor layer ((Al_{0.3}Ga_{0.7})_{0.5}In_{0.5}P). Thus, the refraction angle θ₂ does not directly affect the critical angle at the interface of the low refractive index surface layer (Al_{0.5}In_{0.5}P) and air, and thus, an effect of enhancing light extraction efficiency due to the low refractive index of the low refractive index surface layer (Al_{0.5}In_{0.5}P) can be obtained without reducing light extraction efficiency due to the increase in the refraction angle θ₂.

Thus, according to the present exemplary embodiment, because at least one of the first and second conductivity-type semiconductor layers 20 and 40 has depressions and protrusions formed on at least a portion of the surface thereof and includes the low refractive index surface layer 21 having the composition of (AlᵥGa₁₋ᵥ)_{0.5}In_{0.5}P (0.7≦v≦1) or Al_{w}In_{1-w}P(0≦w≦1), a semiconductor light emitting device having significantly enhanced light extraction efficiency can be obtained.

In the present exemplary embodiment, the low refractive index surface layer 21 is illustrated as a portion of the first conductivity-type semiconductor layer 20, but the present disclosure is not limited thereto. For example, the entire first conductivity-type semiconductor layer 20 may be made of the same material as that of the low refractive index surface layer 21.

An intermediate layer 22 having a refractive index greater than that of the low refractive index surface layer 21 may be formed between the low refractive index surface layer 21 and the active layer 30. For example, when the low refractive index surface layer 21 has a composition of Al_{w}In_{1-w}P (0≦w≦1), the intermediate layer 22 may be formed of AlᵤIn₁₋ᵤP (0≦u≦v, w) in which the proportion of aluminum (Al) is smaller than that of the low refractive index surface layer 21. In this case, the intermediate layer 22 has a refractive index greater than that of the low refractive index surface layer 21, thus having a structure in which the refractive indices are sequentially reduced in a light extraction direction to obtain more enhanced light extraction efficiency.

Also, when the low refractive index surface layer 21 has a composition of (AlᵥGa₁₋ᵥ)_{0.5}In_{0.5}P (0.7≦v≦1), intermediate layer 22 may have an empirical formula of AlₘGaₙIn₁₋ₘ₋ₙP (0≦m≦1, 0≦n≦1) in which the proportion of aluminum (Al) is smaller than that of the low refractive index surface layer 21. In this case, a structure in which refractive indices are reduced in the light extraction direction is also formed to obtain more improved light extraction efficiency.

As illustrated in FIG. 1, the first and second electrodes 20a and 40a are electrically connected to each of the corresponding first and second conductivity-type semiconductor layers 20 and 40. The first and second electrodes 20a and 40a can be formed on a surface of each of the first and second conductivity-type semiconductor layers 20 and 40, respectively.

The first electrode 20a may be formed on the first conductivity-type semiconductor layer 20, and the second electrode 40a may be formed on a lower portion of the second conductivity-type semiconductor layer 40. In this case, in order to enhance an ohmic-contact function between the first and second conductivity-type semiconductor layers 20 and 40 and the first and second electrodes 20a and 40a, respectively, first and second contact layers 50 and 60 may be interposed between the first conductivity-type semiconductor layer 20 and the first electrode 20a and between the second conductivity-type semiconductor layer 40 and the second electrode 40a, respectively. As the first and second contact layers 50 and 60, transparent electrodes such as ITO, ZnO, or the like, may be used.

In the present exemplary embodiment, the first and second electrodes 20a and 40a are disposed to face in opposite directions. Alternatively, the first electrode 20a may be formed on the first conductivity-type semiconductor layer 20 in a position exposed by etching portions of the second conductivity-type semiconductor layer 40, the active layer 30, and the first conductivity-type semiconductor layer 20; and the second electrode 40a may be formed on a lower portion of the second conductivity-type semiconductor layer 40. Positions and connection structures of the first and second electrodes 20a and 40a may be variably modified as necessary.

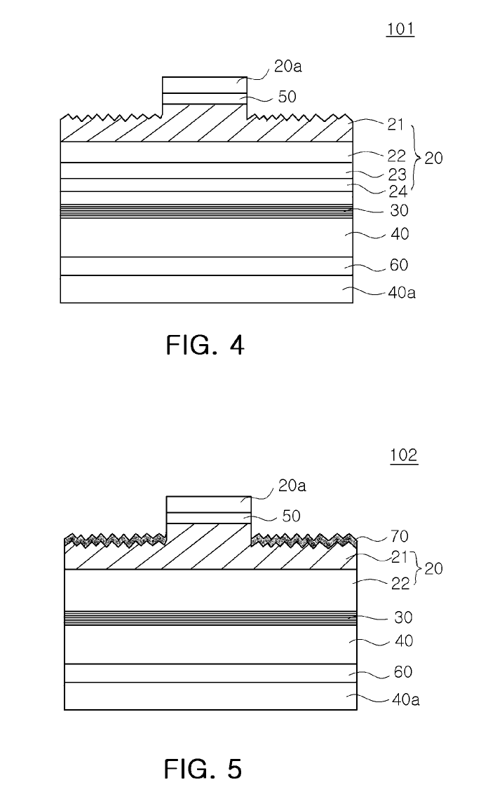

FIG. 4 is a view schematically illustrating a cross-section of a light emitting device according to another exemplary embodiment of the present disclosure.

Referring to FIG. 4, the first conductivity-type semiconductor layer 20 of a light emitting device 101 according to the present exemplary embodiment may include a plurality of intermediate layers 22, 23, and 24 formed between the low refractive index surface layer 21 and the active layer 30, and here, the plurality of intermediate layers 22, 23, and 24 may be made of materials having refractive indices which are sequentially decreased or increased.

The plurality of intermediate layers 22, 23, and 24 have a reflective index greater than that of the low refractive index surface layer 21, and have a smaller refractive index in a direction toward the low refractive index surface layer 21. Namely, the plurality of intermediate layers 22, 23, and 24 have refractive indices which are sequentially decreased in a direction toward the low refractive index surface layer 21 to allow light emitted from the active layer 30 to be effectively extracted to the outside.

For example, the plurality of intermediate layers 22, 23, and 24 may be formed of AlᵤIn₁₋ᵤP (0≦u≦1) AlₘGaₙIn₁₋ₘ₋ₙP (0≦m≦1, 0≦n≦1), and in this case, the proportions of aluminum (Al) in the plurality of intermediate layers 22, 23, and 24 may be increased in a direction toward the low refractive index surface layer 21.

FIG. 5 is a view schematically illustrating a cross-section of a light emitting device according to another exemplary embodiment of the present disclosure.

Referring to FIG. 5, an anti-reflective layer 70 may be formed on the low refractive index surface layer 21 of a light emitting device 102. The anti-reflective layer 70 may be made of a light-transmissive material having a refractive index smaller than that of the low refractive index surface layer 21 and greater than that of air. For example, the anti-reflective layer 70 may be made of a silicon nitride (Si₃N₄) or a silicon oxide (SiO₂).

The anti-reflective layer 70 may be formed on the irregular surface of the low refractive index surface layer 21, and may have the same shape as that of the depressions and protrusions of the irregular surface. Since the anti-reflective layer 70 has a refractive index value between that of the low refractive index surface layer 21 and that of air, a rate of total internal reflection of light when light proceeds from the low refractive index surface layer 21 to the air can be reduced, and thus, light extraction efficiency can be further enhanced.

Table 2 below shows light extraction efficiency of a semiconductor light emitting device according to an exemplary embodiment of the present disclosure. For example, the anti-reflective layer 70 of the light emitting device according to the exemplary embodiment illustrated in FIG. 5 has a thickness of 77.8 nm and is made of Si₃N₄, and refractive indices of the low refractive index surface layer 21 were changed based on the composition from 2.8 to 3.4 to compare light extraction efficiency.

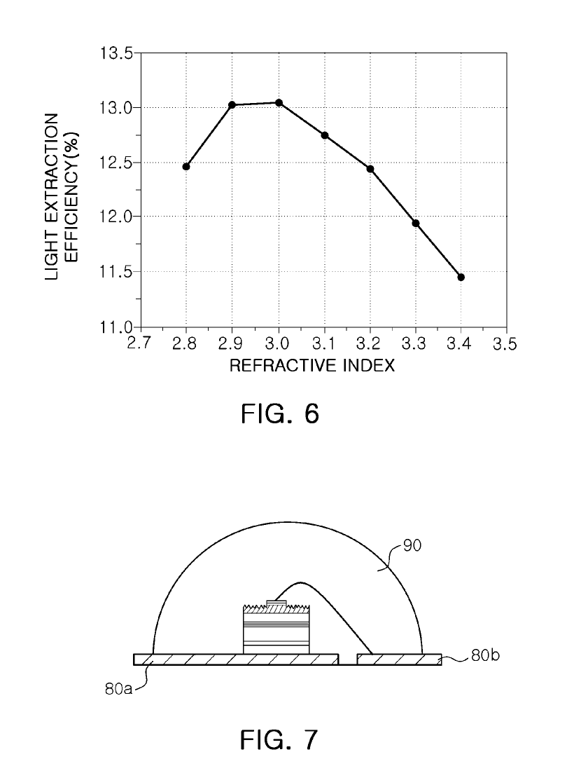

FIG. 6 is a graph showing a change in light extraction efficiency according to refractive indices of the low refractive index surface layer in the semiconductor light emitting device according to an exemplary embodiment of the present disclosure.

TABLE 2

| | Refractive index of low refractive | | | | | | |
|---|---|---|---|---|---|---|---|
| | index surface layer | | | | | | |
| | 2.8 | 2.9 | 3.0 | 3.1 | 3.2 | 3.3 | 3.4 |
| Light extraction | 12.46 | 13.02 | 13.04 | 12.75 | 12.44 | 11.94 | 11.45 |
| efficiency (%) | | | | | | | |

As illustrated in Table 2 and FIG. 6, when the low refractive index surface layer 21 has the composition of AlᵤIn₁₋ᵤP (0≦u≦1) or AlₘGaₙIn₁₋ₘ₋ₙP (0≦m≦1, 0≦n≦1) proposed in the present exemplary embodiment, namely, when the low refractive index surface layer 21 has a refractive index ranging from about 2.8 to 3.2, excellent effects relative to other ranges in terms of light extraction efficiency can be obtained.

FIG. 7 is a cross-sectional view schematically illustrating a package mounting form of the semiconductor light emitting device of FIG. 1. Referring to FIG. 7, a light emitting device package according to the present exemplary embodiment includes first and second terminal units 80a and 80b and a semiconductor light emitting device is electrically connected thereto. In this example, the semiconductor light emitting device can have the same structure as that shown in FIG. 1. The first conductivity-type semiconductor layer 20 may be electrically connected to the second terminal unit 80b by a conductive wire connected to the first electrode 20a, while the second conductivity-type semiconductor layer 40 may be electrically connected to the first terminal unit 80a by the second electrode 40a.

A lens unit 90 may be formed above the semiconductor light emitting device to encapsulate the semiconductor light emitting device, and to fix the semiconductor light emitting device and the first and second terminal units 80a and 80b. The lens unit 90 having, e.g., a hemispherical shape may serve to reduce Fresnel reflection at the interface to increase light extraction, as well as to protect the light emitting device and wires.

Here, the lens unit 90 may be made of a resin; and the resin may include any one or more of epoxy, silicon, strained silicon, a urethane resin, oxetane resin, acryl, polycarbonate, and polyimide. Also, the lens unit 90 may have depressions and protrusions formed on an upper surface thereof to increase light extraction efficiency and to adjust a direction of emitted light. The shape of the lens unit 90 may be variably modified as necessary.

Although not shown, the lens unit 90 may include wavelength conversion phosphor particles for converting a wavelength of light emitted from the active layer of the semiconductor light emitting device 100 (or 101, 102). The phosphor may be a phosphor type which converts a wavelength of light into any one of yellow, red, and green. Alternatively, a plurality of phosphor types may be mixed to convert light into a plurality of wavelengths. The types of phosphor may be determined by a wavelength emitted from the active layer of the semiconductor light emitting device. In detail, the lens unit 90 may include at least one or more of phosphor materials among a YAG-based phosphor material, a TAG-based phosphor material, a silicate-based phosphor material, a sulfide-based phosphor material, and a nitride-based phosphor material.

As set forth above, according to exemplary embodiments of the present disclosure, a semiconductor light emitting device having improved optical power can be provided.

While the present disclosure has been shown and described in connection with exemplary embodiments, it will be apparent to those having ordinary skill in the art that modifications and variations can be made without departing from the spirit and scope of the disclosure as defined by the appended claims.

What is claimed is:

1. A semiconductor light emitting device comprising:
first and second conductivity-type semiconductor layers formed of AlₓGa_{y}In_{1-x-y}P(0≦x≦1, 0≦y≦1, 0≦x+y≦1) or Al_{z}Ga_{1-z}As (0≦z≦1); and
an active layer interposed between the first and second conductivity-type semiconductor layers,
wherein at least one of the first and second conductivity-type semiconductor layers includes a low refractive index surface layer formed of (AlᵥGa₁₋ᵥ)_{0.5}In_{0.5}P (0.7≦v≦1) or Al_{w}In_{1-w}P (0≦w≦1) and having depressions and protrusions.

2. The semiconductor light emitting device of claim 1, wherein the low refractive index surface layer has a composition of Al_{w}In_{1-w}P(0.3≦w≦1).

3. The semiconductor light emitting device of claim 1, further comprising an intermediate layer interposed between the low refractive index surface layer and the active layer, the intermediate layer having a refractive index greater than that of the low refractive index surface layer.

4. The semiconductor light emitting device of claim 3, wherein the intermediate layer has a composition of AlᵤIn₁₋ᵤP (0≦u≦v, w).

5. The semiconductor light emitting device of claim 3, wherein the intermediate layer has a composition of AlₘGaₙIn₁₋ₘ₋ₙP (0≦m≦1, 0≦n≦1).

6. The semiconductor light emitting device of claim 1, further comprising a plurality of intermediate layers interposed between the low refractive index surface layer and the active layer, wherein the plurality of intermediate layers have refractive indices gradually decreased in a direction toward the low refractive index surface layer.

7. The semiconductor light emitting device of claim 6, wherein the plurality of intermediate layers are formed of AlᵤIn₁₋ᵤP (0≦u≦1) and the proportions of aluminum (Al) of the plurality of intermediate layers are gradually increased in the direction toward the low refractive index surface layer.

8. The semiconductor light emitting device of claim 6, wherein the plurality of intermediate layers are formed of AlₘGaₙIn₁₋ₘ₋ₙP (0.3≦m≦1, 0≦n≦1) and the proportions of aluminum (Al) of the plurality of intermediate layers are gradually increased in the direction toward the low refractive index surface layer.

9. The semiconductor light emitting device of claim 1, further comprising an anti-reflective layer formed on the low refractive index surface layer.

10. The semiconductor light emitting device of claim 9, wherein the anti-reflective layer is formed of a silicon nitride or a silicon oxide.

11. The semiconductor light emitting device of claim 1, further comprising a first electrode electrically connected to the first conductivity-type semiconductor layer and a second electrode electrically connected to the second conductivity-type semiconductor layer.

12. The semiconductor light emitting device of claim 11, further comprising a first contact layer interposed between the first conductivity-type semiconductor layer and the first electrode, and a second contact layer interposed between the second conductivity-type semiconductor layer and the second electrode.

13. A semiconductor light emitting device comprising:
a first conductivity-type semiconductor layer;
a second conductivity-type semiconductor layer; and
an active layer interposed between the first and second conductivity-type semiconductor layers,
wherein at least one of the first and second conductivity-type semiconductor layers includes an irregular surface.

14. The semiconductor light emitting device of claim 13, wherein the irregular surface faces away from the active layer.

15. The semiconductor light emitting device of claim 13, wherein the irregular surface forms an interface with air.

16. The semiconductor light emitting device of claim 13, wherein the at least one of the first and second conductivity-type semiconductor layers includes a low refractive index surface layer formed of (AlᵥGa₁₋ᵥ)_{0.5}In_{0.5}P (0.7≦v≦1) or Al_{w}In_{1-w}P (0≦w≦1), the irregular surface being formed on the low refractive index surface layer.

17. The semiconductor light emitting device of claim 13, wherein the at least one of the first and second conductivity-type semiconductor layers has a refractive index which increases in a direction toward the active layer.

18. The semiconductor light emitting device of claim 13, wherein the at least one of the first and second conductivity-type semiconductor layers is formed of (AlᵥGa₁₋ᵥ)_{0.5}In_{0.5}P (0.7≦v≦1) or Al_{w}In_{1-w}P (0≦w≦1).

19. The semiconductor light emitting device of claim 18, wherein the irregular surface faces away from the active layer.

20. The semiconductor light emitting device of claim 18, wherein the irregular surface forms an interface with air.
